(19) United States
(12) Patent Application Publication
(10) Pub. No.: US 2023/0353159 A1
(43) Pub. Date: Nov. 2, 2023

(54) FREQUENCY SYNCHRONIZATION CIRCUIT

(71) Applicant: LAPIS Technology Co., Ltd., Yokohama (JP)

(72) Inventor: Riku TATETSU, Yokohama (JP)

(73) Assignee: LAPIS Technology Co., Ltd., Yokohama (JP)

(21) Appl. No.: 18/305,389

(22) Filed: Apr. 24, 2023

(30) Foreign Application Priority Data
Apr. 28, 2022 (JP) 2022-075453

(51) Int. Cl. H03L 7/099; H03L 7/093

(52) U.S. Cl. CPC H03L 7/0991; H03L 7/093

(57) ABSTRACT

A frequency synchronization circuit includes a digital circuit and a digitally-controlled oscillation circuit. The digital circuit receives a reference clock signal, a multiplication factor signal, and a feedback signal to provide an output signal defining an oscillation frequency. The digitally-controlled oscillation circuit generates a clock signal having a frequency corresponding to the output signal and provides the clock signal to a feedback input and an output. The digital circuit provides, to the output signal, a loop value specified based on the feedback signal, the multiplication factor signal, and the reference clock signal in a closed loop operation, and provides, to the output signal, a value different from the loop value in an open loop operation. The value of the open loop operation enables the digitally-controlled oscillation circuit to oscillate at a frequency equal to or less than a target frequency associated with a reference frequency and a multiplication factor.

### CROSS-REFERENCE TO RELATED APPLICATION

This application claims the priority benefit of Japan application serial no. 2022-075453, filed on Apr. 28, 2022. The entirety of the above-mentioned patent application is hereby incorporated by reference herein and made a part of this specification.

### BACKGROUND

### Technical Field

The disclosure relates to a frequency synchronization circuit.

### Related Art

Japanese Patent Application Laid-Open (JP-A) No. H7-326967 discloses a phase-locked loop circuit including a voltage-controlled oscillator. In this phase-locked loop circuit, an initial value is provided to the voltage-controlled oscillation circuit to stabilize the frequency immediately after start of oscillation.

A frequency synchronization circuit generates a clock signal with a multiplied frequency from a signal indicating a multiplication factor and a reference clock signal. The clock signal is generated by a digitally-controlled oscillation circuit. The digitally-controlled oscillation circuit is controlled according to a filter output value from a digital filter circuit. Based on a feedback from a frequency difference between the reference clock signal and the clock signal rather than a phase difference between the reference clock signal and the clock signal, the frequency synchronization circuit generates the clock signal by the digitally-controlled oscillation circuit. During the lockup process of the frequency synchronization circuit, an overshoot is likely to occur in the frequency of the clock signal.

### SUMMARY

A frequency synchronization circuit according to a first aspect of the disclosure includes a digital circuit and a digitally-controlled oscillation circuit. The digital circuit includes: a first input configured to receive a reference clock signal of a reference frequency from a reference input of the frequency synchronization circuit; a second input configured to receive a multiplication factor signal indicating a multiplication factor from a multiplication input of the frequency synchronization circuit; a feedback input configured to receive a feedback signal; and a loop output configured to provide an output signal defining an oscillation frequency. The digital circuit is configured to perform either a closed loop operation in which a frequency synchronization loop of the frequency synchronization circuit is closed or an open loop operation in which the frequency synchronization loop is opened. The digitally-controlled oscillation circuit is configured to generate a clock signal having a frequency corresponding to the output signal and include a signal output which provides the clock signal to an output of the frequency synchronization circuit and the feedback input. The digital circuit is configured to provide, to the output signal, a loop value specified based on the feedback signal, the multiplication factor signal, and the reference clock signal in the closed loop operation, and provide, to the output signal, a value which is different from the loop value in the open loop operation. The value of the open loop operation enables the digitally-controlled oscillation circuit to oscillate at a frequency equal to or less than a target frequency associated with the reference frequency and the multiplication factor.

As described above, an embodiment of the disclosure provides the frequency synchronization circuit capable of reducing occurrence of an overshoot in the frequency of the clock signal.

### BRIEF DESCRIPTION OF THE DRAWINGS

FIG. 1 is a view showing a configuration of a frequency synchronization circuit according to this embodiment.

FIG. 2 is a view showing a configuration of a frequency synchronization circuit that performs only a closed loop operation.

FIG. 3 is a graph showing a lockup process of the frequency synchronization circuit shown in FIG. 1.

FIG. 4 is a graph showing a lockup process of the frequency synchronization circuit shown in FIG. 2.

### DESCRIPTION OF THE EMBODIMENTS

Embodiments of the disclosure provide a frequency synchronization circuit capable of reducing occurrence of an overshoot in a frequency of a clock signal.

The above and other features of the disclosure will become more apparent in the following detailed description of embodiments of the disclosure with reference to the accompanying drawings. The findings of the disclosure may also be readily understood by considering the following detailed description with reference to the accompanying drawings by way of examples. Hereinafter, embodiments of a frequency synchronization circuit of the disclosure will be described with reference to the accompanying drawings. Wherever possible, the same parts will be labeled with the same reference signs.

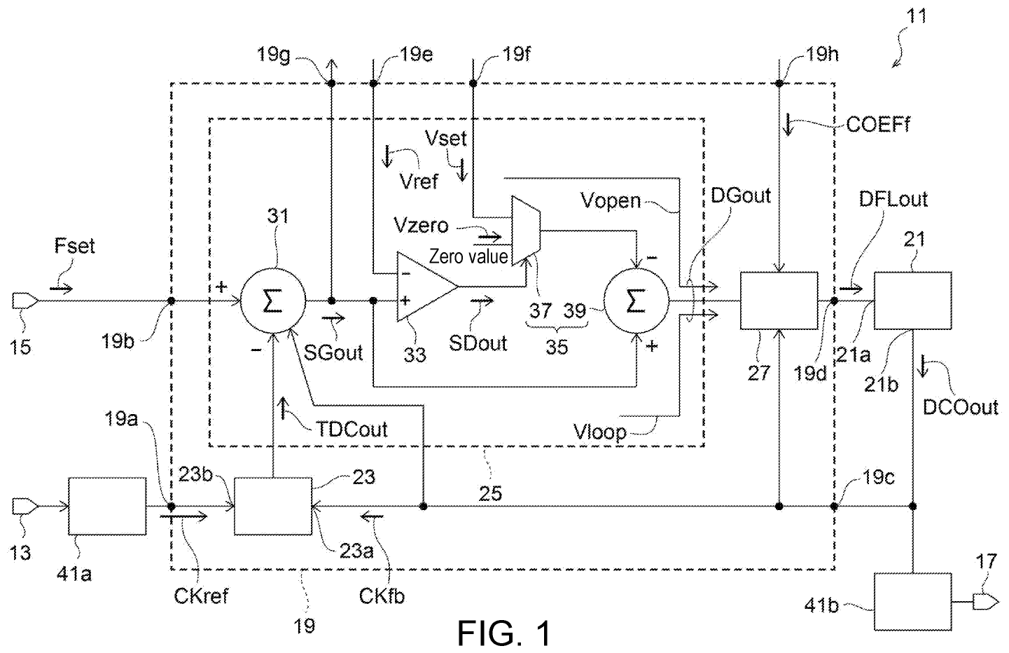

FIG. 1 is a view showing a configuration of a frequency synchronization circuit according to this embodiment. A frequency synchronization circuit 11 includes a reference input 13, a multiplication input 15, an output 17, a digital circuit 19, and a digitally-controlled oscillation circuit 21.

The digital circuit 19 is configured to perform either a closed loop operation in which a frequency synchronization loop of the frequency synchronization circuit 11 is closed or an open loop operation in which the frequency synchronization loop is opened. The digital circuit 19 includes a first input 19a, a second input 19b, a feedback input 19c, and a loop output 19d. In the digital circuit 19, the first input 19a is configured to receive a reference clock signal CKref of a reference frequency from the reference input 13. The second input 19b is configured to receive a multiplication factor signal Fset indicating a multiplication factor from the multiplication input 15. The feedback input 19c is configured to receive a clock signal DCOout as a feedback signal CKfb for the frequency synchronization loop. The loop output 19d provides an output signal DGout that defines an oscillation frequency.

The digitally-controlled oscillation circuit 21 includes a signal input 21a and a signal output 21b. The digitally-controlled oscillation circuit 21 is configured to generate the clock signal DCOout having a frequency corresponding to the output signal DGout received at the signal input 21a, and provide the clock signal DCOout from the signal output 21b to the feedback input 19c and the output 17. The digitally-controlled oscillation circuit 21 may include, for example, an analog oscillator.

The digital circuit 19 is configured to provide, to the output signal DGout, a loop value Vloop specified based on the feedback signal CKfb (clock signal DCOout) from the signal output 21b of the digitally-controlled oscillation circuit 21, the multiplication factor signal Fset, and the reference clock signal CKref in the closed loop operation, and provide, to the output signal DGout, a value Vopen different from the loop value Vloop in the open loop operation.

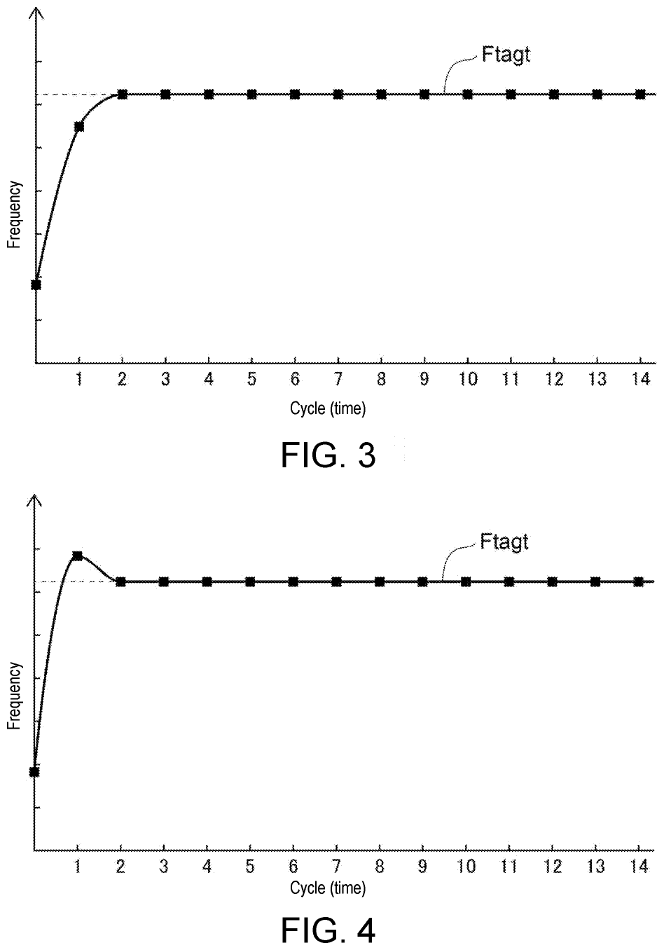

The value Vopen in the open loop operation enables the digitally-controlled oscillation circuit 21 to oscillate at a frequency equal to or less than a target frequency Ftagt (FIG. 3) associated with the reference clock signal CKref and the multiplication factor of the multiplication factor signal Fset.

According to the frequency synchronization circuit 11, in the closed loop operation, the digital circuit 19 updates the loop value Vloop based on the feedback signal CKfb, the multiplication factor signal Fset, and the reference clock signal CKref. The digital circuit 19 provides a signal of the updated loop value Vloop (updated value) to the digitally-controlled oscillation circuit 21.

The digital circuit 19 provides a signal of the value Vopen different from the loop value Vloop to the digitally-controlled oscillation circuit 21 in the open loop operation. The value Vopen of this signal is set in the digital circuit 19. Specifically, the value Vopen is set such that an assumed oscillation frequency corresponding to the value of the output signal DGout is lower than the value of the target frequency Ftagt associated with a product of the reference frequency of the reference clock signal CKref and the multiplication factor of the multiplication factor signal Fset. Thus, with the value Vopen which is different from the updated value obtained based on the feedback signal CKfb, the multiplication factor signal Fset, and the reference clock signal CKref, an overshoot of oscillation frequency, which is likely to occur during the lockup process, is avoided in this cycle.

Referring to FIG. 1, the digital circuit 19 includes a time-to-digital converter (TDC) circuit 23, a signal processing circuit 25, and a digital filter circuit 27.

The TDC circuit 23 receives, at a first input 23a, the clock signal DCOout from the digitally-controlled oscillation circuit 21 as the feedback signal CKfb, and receives, at a second input 23b, the reference clock signal CKref. The TDC circuit 23 is configured to count a quantity of waveform change edges of the feedback signal CKfb between a first edge and a second edge among waveform change edges of the reference clock signal CKref, and generate a digital signal TDCout indicating the count. The waveform change edge of the reference clock signal CKref may be either a rising edge or a falling edge of the reference clock signal CKref, and the first edge and the second edge may be adjacent rising edges or adjacent falling edges. Further, the waveform change edge of the feedback signal CKfb (clock signal DCOout) may be either a rising edge or a falling edge of the feedback signal CKfb (clock signal DCOout). The digital signal TDCout is updated in synchronization with the reference clock signal CKref.

The signal processing circuit 25 is configured to process the multiplication factor signal Fset and the digital signal TDCout to generate the loop value Vloop, and is configured to select the closed loop operation or the open loop operation based on the loop value Vloop.

The digital filter circuit 27 is configured to process the output signal DGout (loop value Vloop or value Vopen) from the signal processing circuit 25 using a changeable filter coefficient COEFf. The filter coefficient COEFf is provided to a filter input 19h.

According to the frequency synchronization circuit 11, the digital circuit 19 has a full digital configuration. Further, the oscillation frequency of the digitally-controlled oscillation circuit 21 is controlled according to a signal DFLout having a digital value from the digital circuit 19. From the signal processing circuit 25, the digital filter circuit 27 receives the loop value Vloop in the closed loop operation and receives the value Vopen in the open loop operation as a value in the open loop operation.

The signal processing circuit 25 includes a first arithmetic circuit 31, a determination circuit 33, and a switching circuit 35. The first arithmetic circuit 31 is configured to generate a difference signal S Gout relating to a difference between the multiplication factor signal Fset and the digital signal TDCout. The determination circuit 33 is configured to determine whether to operate the frequency synchronization circuit 11 in the closed loop operation or the open loop operation based on the value of the difference signal S Gout. The switching circuit 35 is configured to provide, to the output signal DGout, the loop value Vloop in the closed loop operation and the value Vopen in the open loop operation in response to the determination result (SDout) of the determination circuit 33. The determination circuit 33 and the switching circuit are provided between the first arithmetic circuit 31 and the digital filter circuit 27. Specifically, the determination circuit 33 is connected to an output of the first arithmetic circuit 31, and the switching circuit 35 is connected to an output of the determination circuit 33 and provides the loop value Vloop and the value Vopen to the output signal DGout according to the determination result. The determination circuit 33 compares the two digital values according to digital calculation. The switching circuit 35 includes, for example, a selector that switches according to the determination result.

According to the frequency synchronization circuit 11, the switching circuit 35 performs switching of either the closed loop operation or the open loop operation between the first arithmetic circuit 31 and the digital filter circuit 27.

The digital circuit 19 includes a third input 19e that is configured to receive a signal of a reference value Vref associated with the target frequency Ftagt. Accordingly, in this embodiment, the signal of the reference value Vref is provided from outside of the digital circuit 19, but it may also be stored in the digital circuit 19 (e.g., determination circuit 33).

The determination circuit 33 compares the loop value Vloop with the reference value Vref, and generates, as the determination result, a determination signal SDout indicating whether the comparison result between the reference value Vref and the loop value Vloop indicates occurrence of an overshoot in the oscillation frequency of the digitally-controlled oscillation circuit 21.

Based on the feedback signal CKfb (clock signal DCOout), the multiplication factor signal Fset, and the reference clock signal CKref, the digital circuit 19 counts the quantity of waveform change edges (rising edges or falling edges) of the clock signal DCOout (CKfb) in a period (e.g., one cycle of the reference clock signal CKref) between the first edge and the second edge among the waveform change edges of the reference clock signal CKref to generate the digital signal TDCout (updated value) indicating the updated count for each cycle of the reference clock signal CKref.

In the case where an overshoot of oscillation frequency is likely to occur, that is, in the case where the comparison result of the determination circuit 33 indicates occurrence of an overshoot in the oscillation frequency of the digitally-controlled oscillation circuit 21, the frequency synchronization circuit 11 operates to replace the loop value Vloop from the frequency synchronization loop with the value Vopen in the open loop operation. Thus, occurrence of an overshoot of oscillation frequency resulting from the loop value Vloop from the frequency synchronization loop in the digitally-controlled oscillation circuit 21 during the lockup process is reduced.

The digital circuit 19 includes a fourth input 19f that is configured to receive a defined value Vset for use in calculating the value Vopen in the open loop operation.

The digital circuit 19 may include a selector circuit 37 and a second arithmetic circuit 39. The selector circuit 37 is configured to provide a zero value Vzero in the closed loop operation and pass the defined value Vset in the open loop operation in response to the determination result (SDout) of the determination circuit 33. The second arithmetic circuit 39 performs arithmetic operation on a passed signal (zero value Vzero or defined value Vset) from the selector circuit 37 and the loop value Vloop.

According to the frequency synchronization circuit 11, a suitable defined value Vset for the lockup process may be provided via the fourth input 19f. The value Vzero has a zero value.

The switching circuit 35 operates as follows.
Closed loop operation: Vloop=SGout−Vzero (Vzero=0)
Open loop operation: Vopen=SGout−Vset (e.g., Vset=100)

According to this example, the second arithmetic circuit 39 generates a difference signal between the passed signal (zero value Vzero or defined value Vset) from the selector circuit 37 and the loop value Vloop according to arithmetic operation. The determination circuit 33 and the switching circuit 35 (the selector circuit 37 and the second arithmetic circuit 39) operate in synchronization with, for example, the feedback signal CKfb.

As a result, in the open loop operation, the digitally-controlled oscillation circuit 21 is controlled to oscillate at a frequency set lower than the target frequency Ftagt. In the closed loop operation, the digitally-controlled oscillation circuit 21 operates according to the updated value of the frequency synchronization loop.

The first arithmetic circuit 31 and the digital filter circuit 27 receive the clock signal DCOout (CKfb) from the digitally-controlled oscillation circuit 21 and operate using this clock signal.

The digital circuit 19 includes an output 19g that enables the calculation result (value) of the first arithmetic circuit 31 to be outputted from the frequency synchronization circuit 11. The reference value Vref may be specified based on the value of the first arithmetic circuit 31. For example, after the oscillation frequency of the frequency synchronization circuit 11 becomes stable, the value of the first arithmetic circuit 31 indicates a stable oscillation frequency of the frequency synchronization circuit 11.

Further, the reference value Vref may be set such that the selector circuit 37 constantly provides the zero value Vzero in response to the comparison result of the determination circuit 33. In this setting, upon startup of the frequency synchronization circuit 11, an overshoot likely to occur in its lockup process is observed. Based on the result of this observation, it is possible to specify the defined value Vset.

In the frequency synchronization circuit 11, the TDC circuit 23 may receive the reference clock signal CKref from outside of the frequency synchronization circuit 11 via a frequency divider 41a that divides the frequency of the original reference clock signal by ½, which makes the duty of the reference clock signal CKref uniform. Further, in the frequency synchronization circuit 11, the clock signal DCOout of the digitally-controlled oscillation circuit 21 may be provided to the output 17 via a frequency divider 41b that divides the frequency by ½.

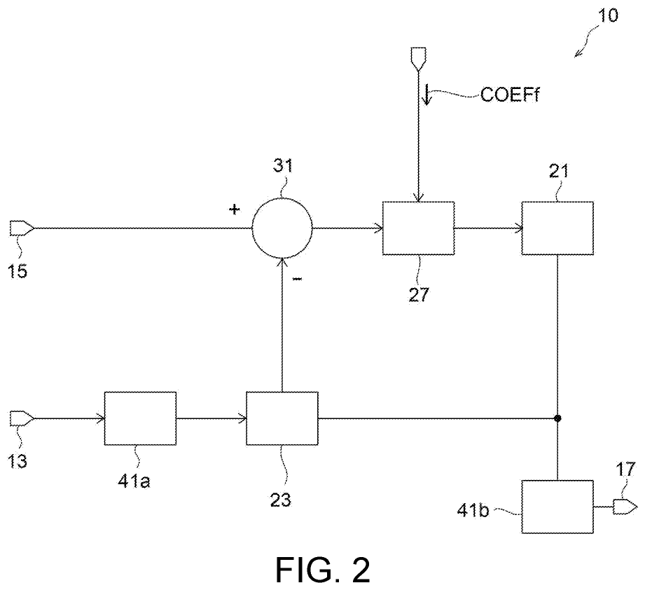

FIG. 2 is a view showing a configuration of a frequency synchronization circuit that performs only a closed loop operation. Referring to FIG. 2, a frequency synchronization circuit is shown. In the frequency synchronization circuit 10, the same or similar parts as those of the frequency synchronization circuit 11 are labeled with the same or similar reference signs, and repeated descriptions thereof will be omitted. FIG. 3 is a graph showing a lockup process of the frequency synchronization circuit shown in FIG. 1. FIG. 4 is a graph showing a lockup process of the frequency synchronization circuit shown in FIG. 2. In FIG. 3 and FIG. 4, the horizontal axis represents the cycle based on the reference clock signal CKref, and the vertical axis represents the oscillation frequency of the digitally-controlled oscillation circuit 21.

The operation of the main circuits of the frequency synchronization circuit 11 of FIG. 1 will be described. In an example, the reference clock signal CKref may be, for example, 32.768 kHz, and the clock signal DCOout may be, for example, 32 MHz.

As already described, the TDC circuit 23 counts the clock quantity of the clock signal DCOout (or CKfb) within one cycle of the reference clock signal CKref to generate the digital signal TDCout. The first arithmetic circuit 31 generates a difference Fdelt between the multiplication factor signal Fset and the digital signal TDCout. Specifically:

Fset−TDCout→Fdelt

The value Fdelt of the difference signal gradually approaches zero during the lockup process.

In the frequency synchronization circuit 10 of FIG. 2, the difference signal of the value Fdelt is provided to the digital filter circuit 27. The digital filter circuit 27 operates as follows such that a current value Fdelt(n) is sequentially added to a previous value Fdelt(n−1). Specifically:

Fdelt(n−1)+Fdelt(n)→Fdelt_pre

The digital filter circuit 27 constantly stores the previous value Fdelt(n−1).

The digital filter circuit 27 calculates the accumulated result value Fdelt_pre with the filter coefficient COEFf.

Fdelt_pre/COEFf→DFLout

According to this example, the arithmetic operation of the digital filter circuit 27 may be division.

The value of the signal DFLout is the quotient of the division without using the remainder. The digital filter circuit 27 operates in synchronization with the feedback signal CKfb.

Referring to FIG. 3, the oscillation frequency of the digitally-controlled oscillation circuit 21 for each cycle during such a lockup process is shown. An overshoot occurs in the second cycle.

At the startup of the frequency synchronization circuit 10 and the frequency synchronization circuit 11, the difference between the digital signal TDCout indicating the count of the TDC circuit 23 and the multiplication factor signal Fset indicating the multiplication factor is large. In the frequency synchronization circuit 10, the digital filter circuit 27 provides the signal DFLout which causes high oscillation in the digitally-controlled oscillation circuit 21 based on a large difference signal. On the other hand, in the frequency synchronization circuit 11, the determination circuit 33 prevents a large difference signal from being provided to the digital filter circuit 27 while the switching circuit 35 performs determination of switching the frequency synchronization circuit 11 to the open loop operation.

Referring to FIG. 3, the frequency synchronization circuit 11 performs lockup in the closed loop operation (Vloop=Vloop−Vzero (Vzero=0)) after startup. When the determination circuit 33 determines that the oscillation frequency exceeds the target frequency based on the updated value of the frequency synchronization loop in the lockup process, in this cycle, the switching circuit 35 switches to the open loop operation (Vopen=Vloop−Vset). In the next cycle, the determination circuit 33 determines the difference signal SGout again.

As described above, this embodiment provides the frequency synchronization circuit 11 capable of reducing occurrence of an overshoot in the frequency of the clock signal.

Although the principles of the disclosure have been illustrated and described in the exemplary embodiments, it will be recognized by those skilled in the art that the disclosure may be modified in the arrangements and details without departing from such principles. The disclosure is not limited to the specific configurations disclosed in the embodiments. Thus, all modifications and variations that come within the scope and spirit of the following claims are covered by the disclosure.

What is claimed is:

1. A frequency synchronization circuit comprising:
a digital circuit comprising: a first input configured to receive a reference clock signal of a reference frequency from a reference input of the frequency synchronization circuit; a second input configured to receive a multiplication factor signal indicating a multiplication factor from a multiplication input of the frequency synchronization circuit; a feedback input configured to receive a feedback signal; and a loop output configured to provide an output signal defining an oscillation frequency, wherein the digital circuit is configured to perform either a closed loop operation in which a frequency synchronization loop of the frequency synchronization circuit is closed or an open loop operation in which the frequency synchronization loop is opened; and
a digitally-controlled oscillation circuit configured to generate a clock signal having a frequency corresponding to the output signal and comprise a signal output which provides the clock signal to an output of the frequency synchronization circuit and the feedback input, wherein the digital circuit is configured to provide, to the output signal, a loop value specified based on the feedback signal, the multiplication factor signal, and the reference clock signal in the closed loop operation, and provide, to the output signal, a value which is different from the loop value in the open loop operation, and
the value of the open loop operation enables the digitally-controlled oscillation circuit to oscillate at a frequency equal to or less than a target frequency associated with the reference frequency and the multiplication factor.

2. The frequency synchronization circuit according to claim 1, wherein the digital circuit comprises:
a TDC circuit configured to receive the clock signal from the digitally-controlled oscillation circuit and the reference clock signal to count a quantity of waveform change edges of the clock signal between a first edge and a second edge among waveform change edges of the reference clock signal, and generate a digital signal indicating the count;
a signal processing circuit configured to process the multiplication factor signal and the digital signal to generate the loop value, and select the closed loop operation or the open loop operation based on the loop value; and
a digital filter circuit configured to process a signal from the signal processing circuit using a changeable filter coefficient.

3. The frequency synchronization circuit according to claim 2, wherein the signal processing circuit comprises:
a first arithmetic circuit configured to generate a difference signal relating to a difference between the multiplication factor signal and the digital signal;
a determination circuit configured to determine whether to operate the frequency synchronization circuit in the closed loop operation or the open loop operation based on a value of the difference signal; and
a switching circuit configured to provide, to the output signal, the loop value in the closed loop operation and the value of the open loop operation in the open loop operation in response to a determination result of the determination circuit.

4. The frequency synchronization circuit according to claim 3, wherein
the digital circuit comprises a third input configured to receive a reference value associated with the target frequency, and
the determination circuit compares the loop value with the reference value to generate, as the determination result, a determination signal indicating whether a result of comparison between the reference value and the loop value indicates occurrence of an overshoot in oscillation frequency of the digitally-controlled oscillation circuit.

5. The frequency synchronization circuit according to claim 4, wherein
the digital circuit comprises a fourth input which receives a defined value for use in calculating the value of the open loop operation, and
the digital circuit comprises:
a selector circuit configured to provide a zero value in the closed loop operation and provide the defined value in the open loop operation in response to the determination result of the determination circuit; and
a second arithmetic circuit configured to perform arithmetic operation on the zero value or the defined value from the selector circuit and the loop value to generate the output signal.
